(19) United States
(12) Patent Application Publication
(10) Pub. No.: US 2017/0322130 A1
(43) Pub. Date: Nov. 9, 2017

(54) SENSING METHOD

(71) Applicant: NIHON DEMPA KOGYO CO., LTD., Tokyo (JP)

(72) Inventor: Wakako SHINOBU, Saitama (JP)

(73) Assignee: NIHON DEMPA KOGYO CO., LTD., Tokyo (JP)

(21) Appl. No.: 15/525,290

(22) PCT Filed: Sep. 25, 2015
(86) PCT No.: PCT/JP2015/077017

§ 371 Date: May 9, 2017

(30) Foreign Application Priority Data
Nov. 11, 2014 (JP) 2014-229280

(51) Int. Cl. G01N 5/02; G01N 1/40; H03B 5/32; H03H 9/13

(52) U.S. Cl. CPC G01N 5/02; H03H 9/132; G01N 1/405; H03B 5/32

(57) ABSTRACT

To provide a technique for performing a highly reliable measurement in sensing a sensing object in a sample solution based on a frequency variation of the crystal resonator 4. In a sensing method that causes the sensing object to attach to the crystal resonator 4 and measures an amount of the sensing object from the frequency variation caused by an effect of mass addition, an oscillation frequency is measured before a measurement region is caused to be in a liquid phase, and subsequently the sample solution is supplied to the measurement region. Thereafter, a liquid component in the measurement region is removed to cause the measurement region to be in a gas phase. An oscillation frequency is measured to measure a frequency difference from the oscillation frequency before the sample solution is supplied to the measurement region. Therefore, since a piezoelectric resonator oscillates in the gas phase, an error of the oscillation frequency and a decrease in a variation amount of the oscillation frequency caused by the crystal resonator 4 contacting a liquid phase are restrained, thus ensuring sensing the sensing object with high accuracy.

### TECHNICAL FIELD

The present invention relates to a technique for sensing a sensing object using a piezoelectric resonator.

### BACKGROUND ART

In a clinical field, a simple inspection method called POCT (Point of core TEST), which is typified by, for example, a self-monitoring of blood glucose level and an influenza virus inspection is spreading. In this inspection, there is known a method using QCM (Quartz Crystal Microbalance) disclosed in Patent Document 1. A brief description of the QCM is as follows. A sensing object in a sample solution is adsorbed on a surface of a crystal resonator disposed in a sensing device. An effect of mass addition corresponding to an adsorbed amount of the sensing object varies an oscillation frequency of the crystal resonator. Based on this variation of the oscillation frequency, detection or quantitative determination of the sensing object in the sample solution is performed.

Recently, detection of further small amount of the sensing object is desired for the purpose of, for example, a prevention of a virus spread and an early detection of a cancer marker. It is desired to measure a mass in the order of pg per 1 ml.

For such problem, there is known, what is called a sensitization, a method for increasing an amount of frequency variation by adding a larger molecule than a low-molecular substance having a property that binds to a low-molecular substance, which is the sensing object, and causing the larger molecule to bind to the low-molecular substance. However, in the case where a particle larger than a certain size or more is bound to the sensing object, as described in Non-patent Documents 1 and 2, there is known a phenomenon in which the effect of mass addition cannot be obtained since the particle adsorbed on the surface of the crystal resonator oscillates at a unique frequency that is different from that of the crystal. Thus, regardless of adding the particles for the purpose of the sensitization, there has been a case where sensitivity is reduced on the contrary.

Patent Document 2 describes a method to sensitize frequency amplitude by adding a molecule with a large grain diameter compared with a measurement object and a crosslinkable compound. Patent Document 3 discloses a method to increase a surface area of the thin film to achieve sensitizing the frequency amplitude by causing the particles to attach to a thin film that adsorbs the measurement object and then removing these particles. However, these do not solve the problems to be solved by the present invention.

### CITATION LIST

Patent Document
Patent Document 1: Japanese Unexamined Patent Application Publication No. 2007-178348
Patent Document 2: Japanese Unexamined Patent Application Publication No. 2006-275864
Patent Document 3: Japanese Unexamined Patent Application Publication No. 2007-147556

### Non-Patent Document

Non-patent Document 1: A sensitive new method for the determination of adhesive bonding between a particle and a substrate, J. Appl. Phys. 58(7), 1, October 1985

Non-patent Document 2: Positive Frequency Shift Observed Upon Adsorbing Micron-Sized Solid Objects to a Quartz Crystal Microbalance from the Liquid Phase, Anal. Chem. 2010, 82, pp. 2237-2242

### SUMMARY

### Problems to be Solved

The present invention has been made under such circumstances, and an object thereof is to provide a technique that ensures a highly reliable measurement in sensing a sensing object in a sample solution based on a frequency variation of a piezoelectric resonator.

### Solutions to the Problems

A sensing method of the present invention uses a sensing sensor made by forming an adsorbing layer on a surface of an electrode of a piezoelectric resonator. The adsorbing layer adsorbs a component as a sensing object in a sample solution, and supplies the sample solution to a measurement region of the sensing sensor to measure an amount of the component as an amount of frequency variation of the piezoelectric resonator before and after adsorption. The sensing method includes: a step of oscillating the piezoelectric resonator using an oscillator circuit and measuring an oscillation frequency before the measurement region becomes in a liquid phase; a step of subsequently supplying the sample solution to the measurement region; a step of subsequently removing a liquid from the measurement region so as to cause the measurement region to be in a gas phase; and a step of subsequently measuring an oscillation frequency by oscillating the piezoelectric resonator using the oscillator circuit, and measuring an amount of frequency variation between the oscillation frequency and the oscillation frequency before the measurement region becomes in the liquid phase.

The sensing method of the present invention may include: a step of supplying a liquid to the measurement region after the step of supplying the sample solution to the measurement region and before the step of causing the measurement region to be in the gas phase. The liquid contains a group of particles for sensitization having a property of adsorbing on a corresponding portion of the sensing object. The sensing method of the present invention may include: a step of supplying a crosslinking agent that forms a cross-linkage between the sensing object and the adsorbing layer to the measurement region, after the step of supplying the sample solution to the measurement region and before the step of causing the measurement region to be in the gas phase.

Furthermore, the sensing method of the present invention may include: a step of supplying a crosslinking agent that forms cross-linkages between the particles for sensitization having the property of adsorbing on the corresponding portion of the sensing object and the sensing object, and between the sensing object and the adsorbing layer to the measurement region, after the step of supplying the liquid containing the group of particles having the property of adsorbing on the corresponding portion of the sensing object and before the step of causing the measurement region to be in the gas phase.

Alternatively, the sensing method of the present invention may include: a step of supplying a thinner solution to the measurement region, before the step of supplying the sample solution to the measurement region. The sensing method of the present invention may include: a step of supplying an organic solvent to the measurement region before the step of causing the measurement region to be in the gas phase, and the step of causing the measurement region to be in the gas phase includes a step of removing the organic solvent to cause the measurement region to be in a gas phase.

### Effects of the Invention

According to the present invention, in a sensing method that causes a sensing object to attach to a piezoelectric resonator and measures an amount of the sensing object from a frequency variation caused by an effect of mass addition, an oscillation frequency is measured before a measurement region of the piezoelectric resonator is caused to be in a liquid phase, and subsequently a sample solution is supplied to the measurement region. Thereafter, a liquid component on the measurement region is removed to cause the measurement region to be in a gas phase. An oscillation frequency is measured to measure a frequency difference from the oscillation frequency before the sample solution is supplied to the measurement region. Therefore, since a piezoelectric resonator oscillates in the gas phase, an error of the oscillation frequency and a decrease in a variation amount of the oscillation frequency caused by the piezoelectric resonator contacting a liquid phase are restrained, thus ensuring sensing the sensing object with high accuracy.

### BRIEF DESCRIPTION OF THE DRAWINGS

FIG. 1 is a perspective view of a sensing device and a sensing sensor according to the present invention.

FIG. 2 is an exploded perspective view of the sensing sensor.

FIG. 3 is an exploded perspective view illustrating top surface sides of respective portions of the sensing sensor.

FIG. 4 is an exploded perspective view illustrating a lower surface side of a part of the sensing sensor.

FIG. 5 is a longitudinal sectional side view of the sensing sensor.

FIG. 6 is a schematic configuration diagram of the sensing device.

FIG. 7 is a characteristic diagram illustrating a variation of an oscillation frequency when the sensing device measures a sample.

FIG. 8 is a schematic diagram of a surface of a crystal resonator.

FIG. 9 is a schematic diagram of the surface of the crystal resonator.

FIG. 10 is a schematic diagram of the surface of the crystal resonator.

FIG. 11 is a schematic diagram of the surface of the crystal resonator.

FIG. 12 is a schematic diagram of the surface of the crystal resonator and a supply channel.

FIG. 13 is an explanatory drawing illustrating a removal method of a liquid component in the supply channel.

FIG. 14 is a schematic diagram representing a variation of a resonance frequency caused by a particle binding to a surface of the crystal resonator.

FIG. 15 is a characteristic diagram illustrating a variation of an oscillation frequency under a liquid phase when the sensing device measures the sample.

### DESCRIPTION OF EMBODIMENTS

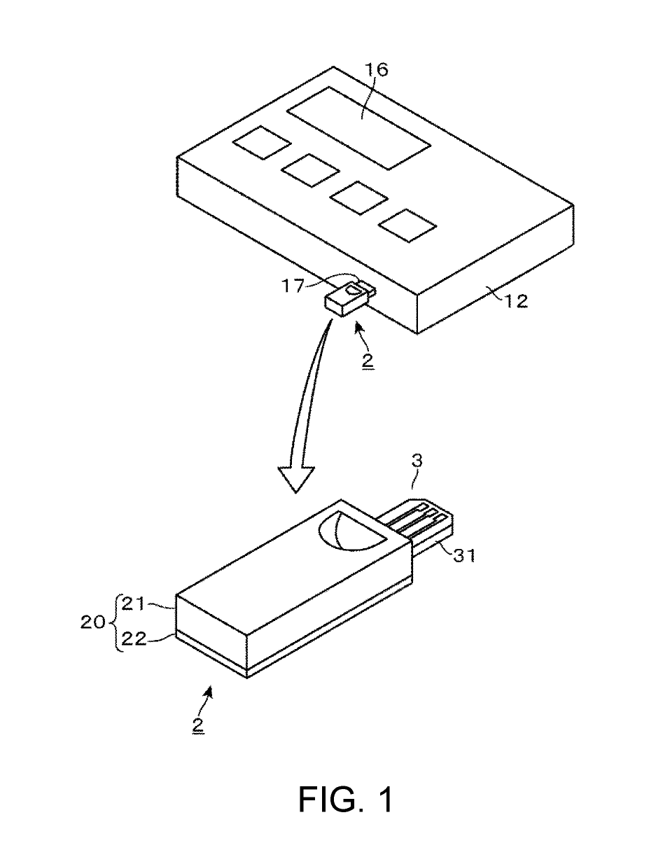

The following describes a sensing device using a sensing sensor according to an embodiment of the present invention. This sensing device uses a microfluidic chip. The sensing device can detect, for example, presence/absence of an antigen, such as virus, in a sample solution obtained from nasal cavity swab of a human so as to determine whether the human has been infected with a virus or not with a microfluidic chip. As illustrated in an external perspective view in FIG. 1, the sensing device includes an oscillator circuit unit 12 and a sensing sensor 2. The sensing sensor 2 is attachably/detachably connected to an insertion port 17 that is formed in the oscillator circuit unit 12. The oscillator circuit unit 12 includes, for example, a display 16 constituted by a liquid crystal display screen on a top surface. The display 16 displays, for example, output frequency of an oscillator circuit, which is disposed in the oscillator circuit unit 12 and will be described later, a measurement result, such as an amount of frequency variation, presence/absence of detected virus or a similar result.

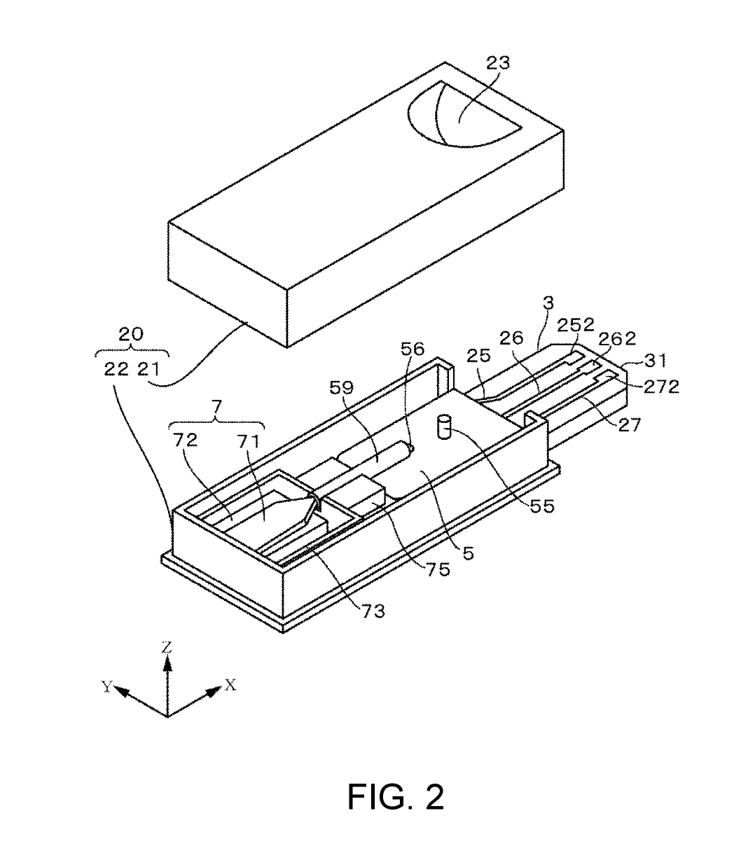

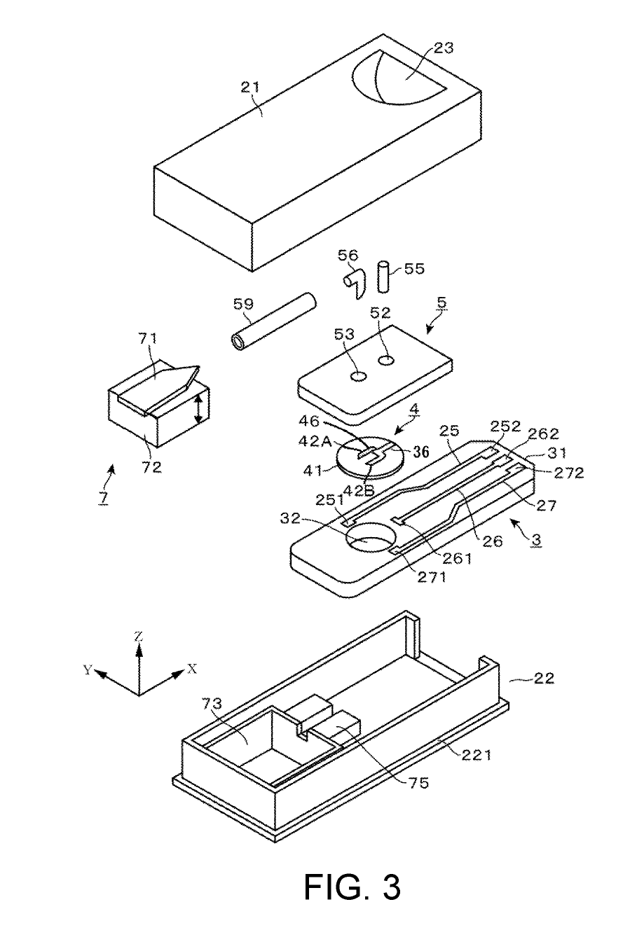

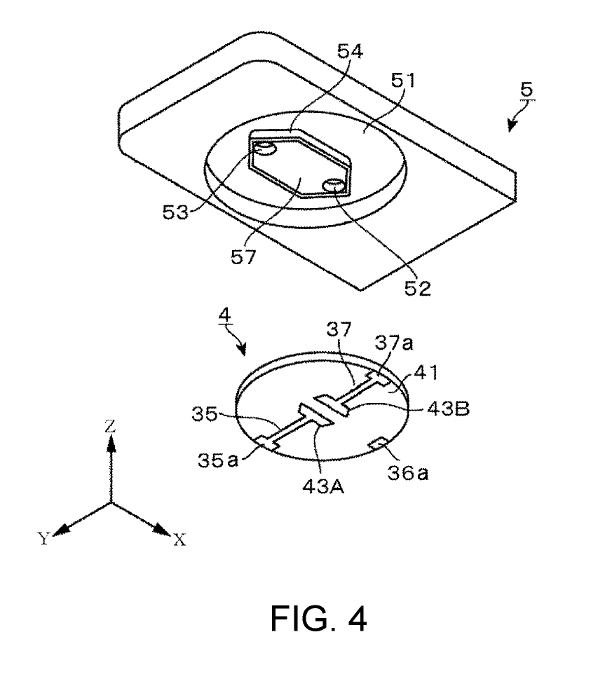

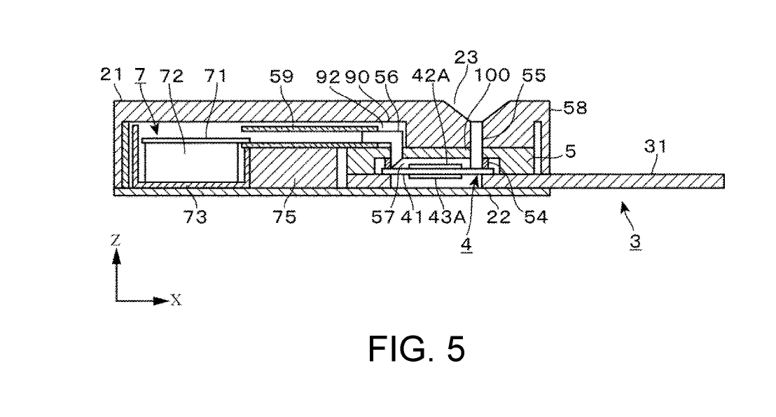

Next, the sensing sensor 2 will be described. FIG. 2 is a perspective view illustrating the sensing sensor 2, which is illustrated in FIG. 1, in a state where an upper-side cover body 21 is removed. FIG. 3 and FIG. 4 are perspective views illustrating a front side (top surface side) of respective members of the sensing sensor 2 and a back side (lower surface side) of some members, respectively. FIG. 5 illustrates a vertical cross-sectional view of the sensing sensor 2 cut along a longitudinal direction.

The sensing sensor 2 includes, as illustrated in FIG. 1, a container 20 constituted of the upper-side cover body 21 and a lower-side case 22. On an upper side of the lower-side case 22, a wiring board 3 in a shape extending in the longitudinal direction is disposed. In one end side of the wiring board 3 in the longitudinal direction, an insertion portion 31, which is inserted into the insertion port 17 of the oscillator circuit unit 12 described above, is formed.

In the wiring board 3, a through hole 32 is formed. The wiring board 3 is arranged in the upper side of the lower-side case 22 such that the through hole 32 is covered by a bottom surface of the lower-side case 22 and the insertion portion 31 projects out of the lower-side case 22. On a front surface side of the wiring board 3, three wirings 25 to 27 extending in the longitudinal direction are disposed. One end sides of the wirings 25 to 27 in the insertion portion 31 include respective terminal portions 252, 262, and 272, and the other end sides include respective terminal portions 251, 261 and 271 at an outer edge of the through hole 32.

A crystal resonator 4 includes, for example, an AT-cut circular plate-shaped crystal element 41. On a front surface side of the crystal element 41, excitation electrodes 42A and 42B, which are made of, for example, Au (gold) are disposed so as to extend in parallel with one another. The excitation electrodes 42A and 42B have one end sides in the longitudinal direction connected. From the connected portion, an extraction electrode 36 is extended toward a peripheral edge of the crystal element 41. This extraction electrode 36 is extended around a side surface of the crystal element 41 to form a terminal portion 36a at the peripheral edge portion on a back surface. On the back surface side of the crystal resonator 4, respective excitation electrodes 43A and 43B, made of, for example, Au, extend in parallel so as to oppose the excitation electrodes 42A and 42B. From the excitation electrodes 43A and 43B, respective extraction electrodes 35 and 37 are extracted toward the peripheral edge of a crystal element 30 to form respective terminal portions 35a and 37a at the peripheral edge portion of the crystal element 41.

A surface of the excitation electrode 42A in a front side of the crystal resonator 4 forms an adsorbing layer 46, which is made of antibodies to adsorb a sensing object, such as an antigen. Meanwhile, a surface of the excitation electrode 42B does not form the adsorbing layer 46 and is exposed.

The crystal resonator 4 is disposed such that the excitation electrode 43A and 43B on the back surface side face the through hole 32 of the wiring board 3 and the terminal portions 35a, 36a, and 37a respectively overlap the corresponding terminal portions 251, 261, and 271 disposed on a wiring board 4. Then, the crystal resonator 4 is adhered using a conductive adhesive. In view of this, the crystal resonator 4 is secured to the wiring board 3 in an approximately horizontal state.

On an opposite side of the insertion portion 31 on the front side of the wiring board 3, a channel forming member 5 is laminated so as to interpose the crystal resonator 4. On a back side of the channel forming member 5, as illustrated in FIG. 4, a depressed portion 51 is formed to house the crystal resonator 4. In this depressed portion 51, through holes 52 and 53, which penetrate the channel forming member 5 in a thickness direction toward the crystal resonator 4, are formed and a framing portion 54, which surrounds the through holes 52 and 53, is disposed.

When the channel forming member 5 is laminated over the crystal resonator 4, the excitation electrodes 42A and 42B are housed in a region surrounded by the framing portion 54 and the through holes 52 and 53 are arranged aligning in the longitudinal direction of the excitation electrodes 42A and 42B. This region surrounded by the framing portion 54 and the crystal resonator 4 includes a horizontal ceiling surface and has a bottom surface forming a supply channel 57, which is constituted by the crystal resonator 4.

As illustrated in FIG. 3, the through holes 52 and 53 attachably/detachably include an inlet-side capillary member 55 and an outlet-side capillary member 56 each constituted of a porous member.

The inlet-side capillary member 55 is disposed so as to cover the through hole 52. An upper end of the inlet-side capillary member 55 is disposed to be exposed to an inject port 23, which will be described later, formed in the upper-side cover body 21 and a lower end is disposed to enter into the supply channel 57. The outlet-side capillary member 56 is formed in an L-shape that extends upward then bends to extend horizontally. The outlet-side capillary member 56 is disposed so as to cover the through hole 53. A lower end of the outlet-side capillary member 56 is disposed to enter into the supply channel 57. Further, the lower end of the outlet-side capillary member 56 is formed to be inclined.

The other end side of the outlet-side capillary member 56 is connected to one end side of an effluent channel 59 constituted of a glass tube. The other end side of the effluent channel 59 is connected to an effluent absorbing portion 7, which is constituted of, for example, a capillary sheet 71, which suctions liquid flown from the effluent channel 59, and an absorbing member 72, which absorbs liquid suctioned by the capillary sheet 71. A case body 73 to prevent a liquid leakage from the absorbing member 72 is disposed outside the effluent absorbing portion 7. Reference numeral 75 in the drawing is a supporting member that supports the effluent channel 59.

The upper-side cover body 21 is disposed so as to cover the wiring board 3 except for the insertion portion 31, the channel forming member 5, and the effluent absorbing portion 7 from the upper side. The top surface side of the upper-side cover body 21 includes the inject port 23 inclined in a cone shape. The above-mentioned inlet-side capillary member 55 is exposed to a bottom portion of the inject port 23. At this time, a pressing portion 58 disposed on a lower surface of the upper-side cover body 21 presses the channel forming member 5 onto the wiring board 3. In this sensing sensor 2, a process liquid supplied to the inject port 23 flows by capillarity through a consecutive channel that runs from the inject port 23→the inlet-side capillary member 55→a supply channel 40→the outlet-side capillary member 56→the effluent channel 59→the effluent absorbing portion 7.

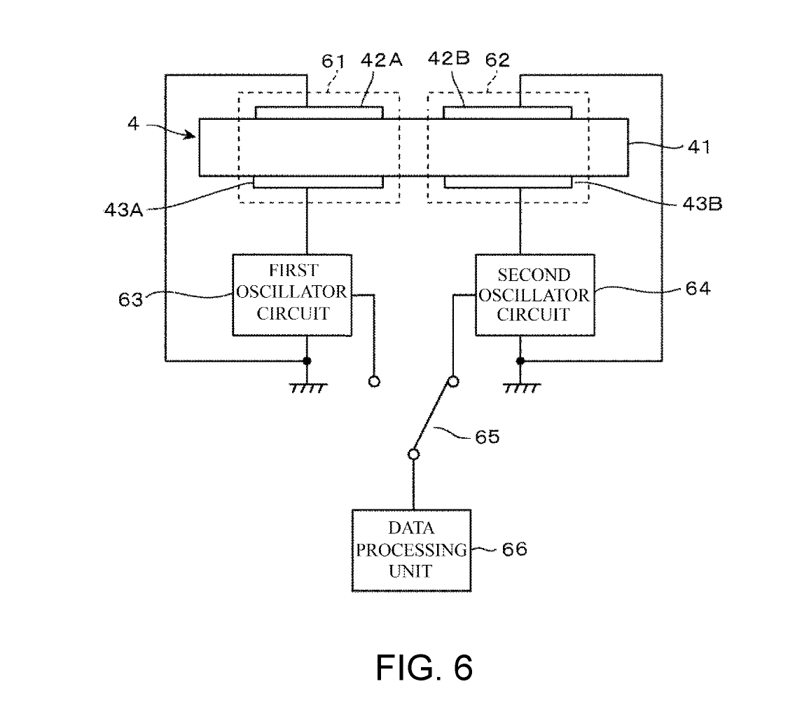

Subsequently, a description will be given of the whole configuration of the sensing device. Inserting the insertion portion 31 of the above-described sensing sensor 2 into the oscillator circuit unit 12 electrically connects the terminal portions 252, 262, and 272 formed in the insertion portion 31 to connecting terminal portions (not illustrated) formed in the oscillator circuit unit 12 to correspond to these terminal portions 252, 262, and 272, and constitutes the sensing device. As illustrated in FIG. 6, a first oscillator circuit 63 and a second oscillator circuit 64 that are constituted, for example, with Colpitts circuit are arranged in the oscillator circuit unit 12. The first oscillator circuit 63 is constituted to oscillate a first vibrating region 61, which is a region sandwiched between the excitation electrode 42A and the excitation electrode 43A in the crystal resonator 4. The second oscillator circuit 64 is constituted to oscillate a second vibrating region 62, which is a region sandwiched between the excitation electrode 42B and the excitation electrode 43B. The terminal 272 is connected so as to be ground potential in oscillation. The surfaces with the first vibrating region 61 and the second vibrating region 62 in this front surface side correspond to measurement regions.

The output sides of the first oscillator circuit 63 and the second oscillator circuit 64 are connected to a switch 65, and a data processing unit 66 is arranged in the latter part of the switch 65. The data processing unit 66 digitizes a frequency signal that is an input signal, and obtains time-series data of oscillation frequency “F1” output from the first oscillator circuit 63 and time-series data of oscillation frequency “F2” output from the second oscillator circuit 64.

The sensing device of the present invention performs intermittent oscillation by alternately switching a channel one connecting the data processing unit 66 and the first oscillator circuit 63 and a channel two connecting the data processing unit 66 and the second oscillator circuit 64 by the switch 65. Consequently, the sensing device ensures avoiding interference between the two vibrating regions 61 and 62 of the sensing sensor 2 and obtaining the stable frequency signals. Subsequently, these frequency signals are, for example, time-shared and fed into the data processing unit 66. The data processing unit 66 calculates the frequency signals as, for example, digital values, and then performs arithmetic processing based on the time-shared data of the calculated digital values, and then displays the arithmetic operation result, for example, such as presence/absence of antigen on the display 16.

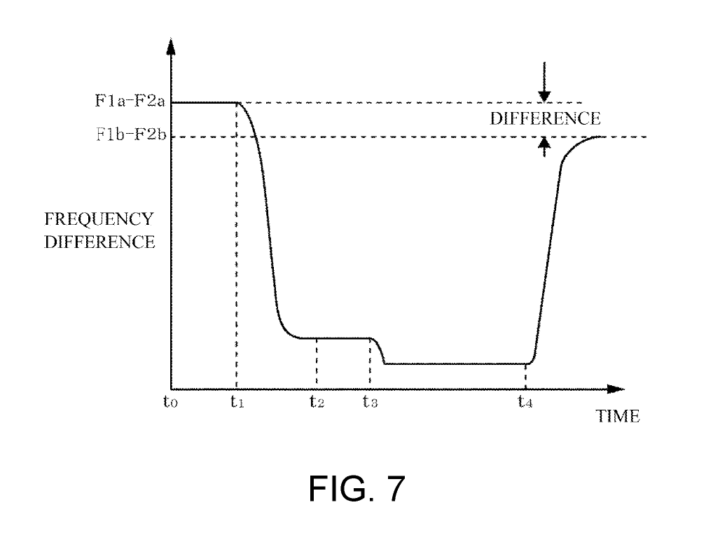

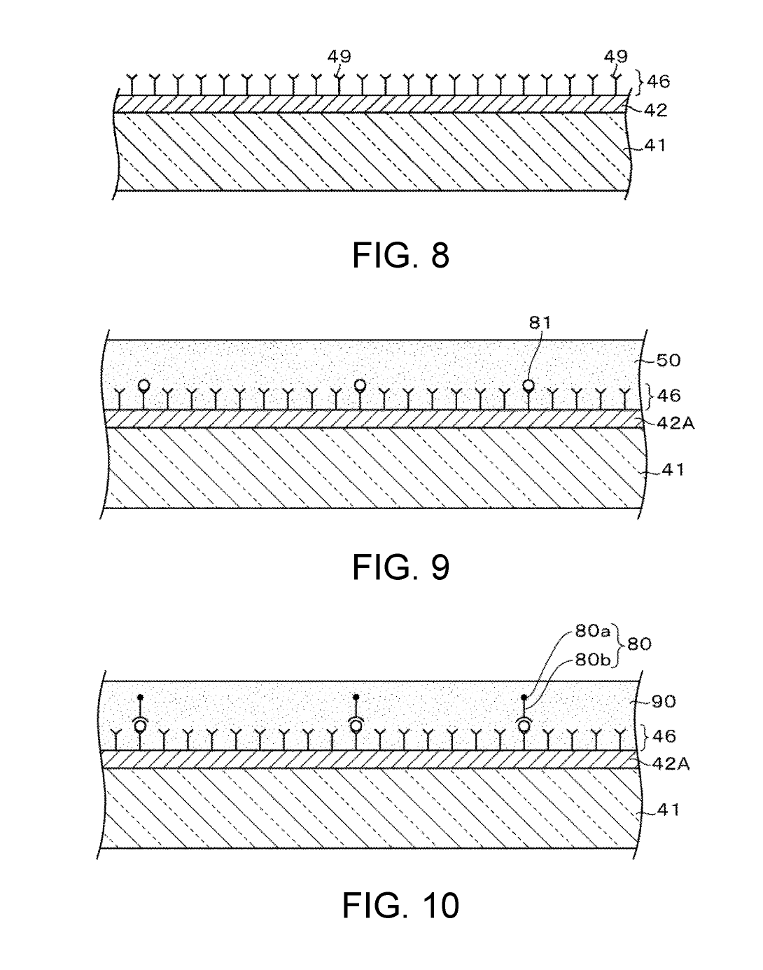

Subsequently, operations of the embodiment of the present invention will be described. FIG. 7 is a characteristic diagram schematically illustrating a time variation of a frequency difference between the oscillation frequencies of the first vibrating region 61 and the second vibrating region 62. FIG. 8 to FIG. 13 are explanatory drawings illustrating states of the surface of the crystal resonator 4 in the sensing sensor 2 in phases. In the schematic diagram n FIG. 7, the variation amount of the frequency difference is exaggeratedly described for convenience of explanation and does not indicate an accurate frequency. First, at Time to, connecting the sensing sensor 2 to the oscillator circuit unit 12 and activating the first and the second oscillator circuits oscillate the first and the second vibrating regions 61 and 62 of the crystal resonator 4, and frequency signals F1a and F2a, which correspond to respective oscillation frequencies before the supply channel 57 becomes in the liquid phase, are taken out. Next, at Time t1, supplying a buffer solution, such as a pure water, a phosphate buffer solution, and a normal saline, from the inject port 23 using a syringe fills the supply channel 57 with the buffer solution and changes a surface of a crystal resonator 44 on a side of the supply channel 57 to be the liquid phase. This causes the oscillation frequency to significantly decrease and the frequency difference F1−F2 also significantly decreases.

Next, at Time t2, a user dropping the sample solution, which is the sensing object, into the inject port 23 using the syringe causes the sample solution to flow from the inlet-side capillary member 55 into the supply channel 57. The antigens in the sample solution do not directly react with the crystal. On the supply channel 57 side of the second vibrating region 62, the excitation electrode 42B is exposed. Therefore, the antigens do not react with this region. Meanwhile, as illustrated in FIG. 8, on the surface of the excitation electrode 42A on the front surface side of the first vibrating region 61, the adsorbing layer 46 is formed by antibodies 49 that selectively react with the antigens. Accordingly, when a sample solution 50 containing the antigens, which are the sensing object, is supplied to the supply channel 57, as illustrated in FIG. 9, antigens 81 contained in the sample solution 50 react with the antibodies 49 formed in the adsorbing layer 46 disposed on the excitation electrode 42A in the first vibrating region 61 and bind to the adsorbing layer 46. While the effect of mass addition of a mass amount of the antigens 81 adsorbed here varies the oscillation frequency, the variation amount of the oscillation frequency is slight when an amount of the antigens 81 contained in the sample solution 50 is small.

After supplying the sample solution, a liquid 90 containing biotinylated antibodies 80, which are made by binding biotins 80a to antibodies 80b, is dropped to the inject port 23 to bind the biotinylated antibody 80 to the antigen 81. As a result of this, the antigen 81 and the biotinylated antibody 80 are bound, as illustrated in FIG. 10, to form a state in which the antigen 81 and the biotinylated antibody 80 are bound on the antibody 49 formed in the adsorbing layer 46.

Then, at Time t3, a liquid 91 containing sensitizer particles 82 is injected to the inject port 23. The sensitizer particle 82 is constituted of, for example, a gold colloid in a size of approximately 200 nm to 3000 nm. A surface of the sensitizer particle 82 is processed by avidin particles 48 so as to bind to the biotin 80a on the biotinylated antibody 80.

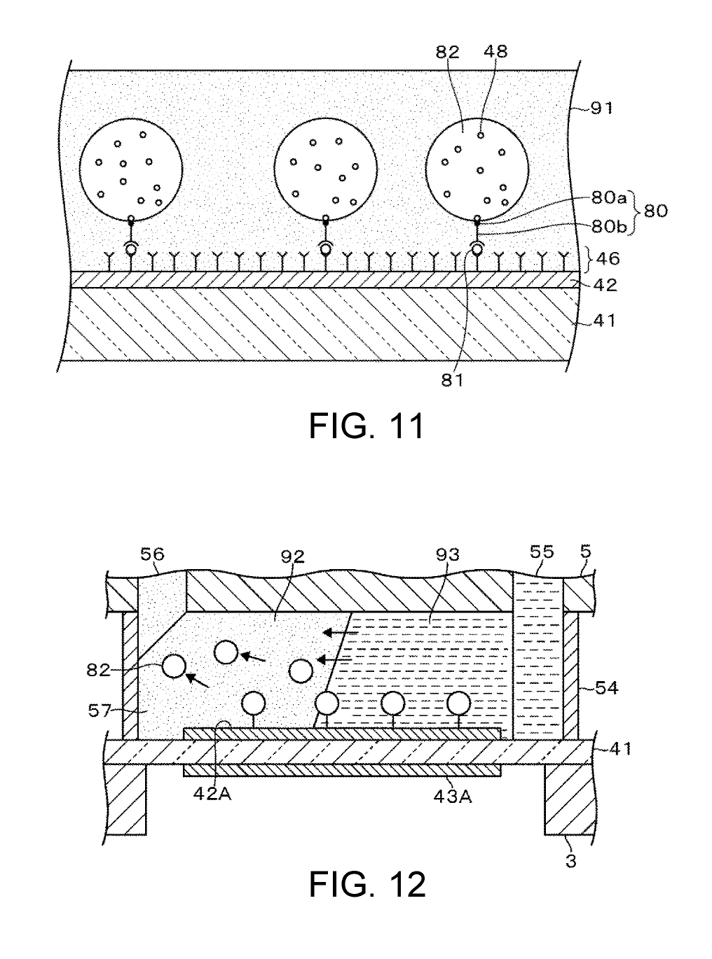

The avidin particle 48 and the biotinylated antibody 80 are bound with ratio of 1:1. Therefore, when the solution 91 containing the sensitizer particles 82 is supplied to the supply channel 57, the sensitizer particle 82 superimposes and binds to the antigen 81, which is bound to the adsorbing layer 46, via the biotinylated antibody 80 as illustrated in FIG. 11. Since the sensitizer particle 82 is larger in size and heavier in weight than those of the antigen 81, the frequency variation caused by the effect of mass addition is significant. Accordingly, the frequency difference of the output oscillation frequency decreases as illustrated in FIG. 7.

After a predetermined period of time elapses since the solution 91 containing the sensitizer particles 82 is supplied, a solution containing a crosslinking agent, such as EDC (1-Ethyl-3-(3-dimethylaminopropyl)-carbodiimide), is supplied to the inject port 23. The EDC dehydrates and condenses an amino group and a carboxyl group to form an amide bond. Therefore, a cross-linkage is formed between the amino group and the carboxyl group between respective protein molecules between the biotinylated antibody 80 and the antigen 81 and between the antigen 81 and the antibody 49. Thus, the sensitizer particle 82, the biotinylated antibody 80, and the antigen 81 are less likely to separate from the adsorbing layer.

Furthermore, a pure water is dropped to the inject port 23. As illustrated in FIG. 12, this causes a solution 92, which contains the crosslinking agent, filling inside the supply channel 57 to be extruded by a pure water 93 and washes away the excessive sensitizer particles 82 and the crosslinking agent. Thereafter, when an organic solvent, such as methanol, is dropped to the inject port 23, the pure water filling the supply channel 57 is replaced by the methanol.

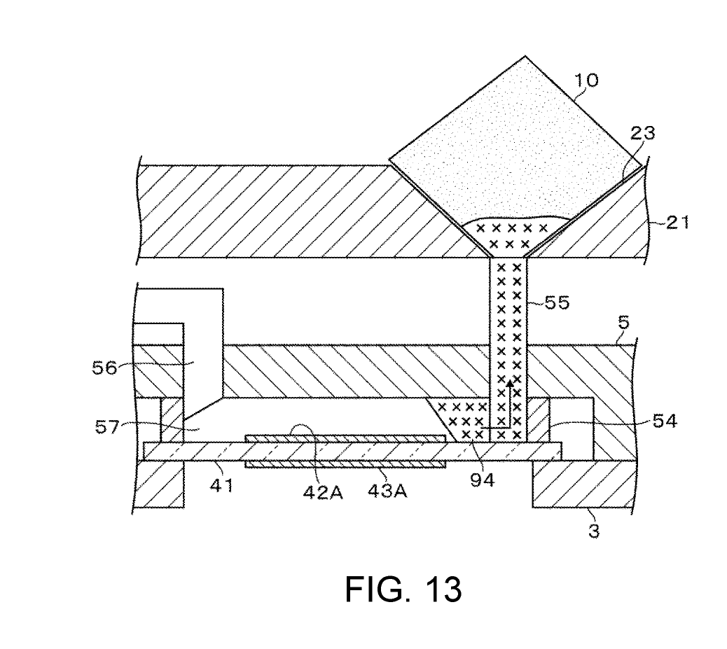

As illustrated in FIG. 13, at Time t4, placing a sponge 10 constituted of, for example, polyvinyl alcohol, on the inject port 23 causes a methanol 94 filling inside the supply channel 57 to flow through the inlet-side capillary member 55 and to be suctioned and removed by the sponge 10, thus causing the inside of the supply channel 57 to be in a gas phase. Furthermore, the pure water is replaced by the methanol 94 in advance, and a liquid component inside the supply channel 57 is suctioned by the sponge 10. Therefore, most of the pure water 92 filling the channel is removed, and furthermore, water attached on the excitation electrodes 42A and 42B, and a wall surface of the supply channel 57 melts into the methanol 94. Thereafter, the sponge 10 suctioning and removing the methanol 94 causes remaining droplets of the methanol 94 attached on the excitation electrodes 42A and 42B, and a wall surface of the supply channel 57 to promptly volatilize and be removed. Accordingly, the liquid component is removed from an entire surface of the excitation electrodes 42A and 42B of the crystal resonator 4, and the entire surface of the excitation electrodes 42A and 42B of the crystal resonator 4 contacts the gas phase.

Since the cross-linkage is formed using the crosslinking agent to strengthen the bond after supplying the liquid 91 containing the sensitizer particles 82 to the excitation electrodes 42A and 42B, the sensitizer particles 82 adsorbed by the adsorbing layer 46 remain in the adsorbing layer 46 with the methanol 94 without being flown away. Therefore, in the adsorbing layer 46 on the first vibrating region 61, the antigens 81 are adsorbed and further, the sensitizer particles 82 are superimposed and bound to the antigens. Accordingly, the oscillation frequency of the first vibrating region 61 becomes a frequency F1b that is decreased from the oscillation frequency of the crystal resonator 4 under the gas phase by the effect of mass addition caused by attachment of the sensitizer particles 82, the biotinylated antibodies 80, and the antigens 81. Meanwhile, the antigens 81 and the sensitizer particles 82 are not adsorbed on the second vibrating region 62. Accordingly, as illustrated in FIG. 7, the oscillation frequency of a second vibrating region 61 becomes a frequency F2b that does not include a decrease of the oscillation frequency caused by the effect of mass addition under the gas phase. Therefore, a frequency difference is calculated by F1b−F2b.

Then, a difference between the frequency difference F1b−F2b of this oscillation frequency and the difference F1a−F2a of the oscillation frequency similarly obtained under the gas phase between the first vibrating region 61 and the second vibrating region 62 and measured before supplying the buffer solution to the supply channel 57 is obtained. For example, a relational expression between this difference and a density of the sensing object in the sample solution is obtained in advance. From this relational expression and a difference obtained from measurement, the density of the sensing object in the sample solution is obtained.

Here, while a description will be given of an effect of oscillating the crystal resonator 4 in the gas phase atmosphere, first, the effect of mass addition on the surface of a piezoelectric resonator will be described. For a relation of an added mass and a frequency before and after the mass is added to the surface of the piezoelectric resonator, a relational expression (Sauerbrey equation) represented by the following formula (1) generally works. The sensitization effect described in the background technique uses this relational expression.

$$Δ m = \frac{S \sqrt{ρ μ}}{2 {NF}^{2}} ( - Δ F ) \qquad ( 1 )$$

Here, Δm is an added mass (g), S is an electrode area (cm²), p is a density (g/cm³) of a piezoelectric resonator, μ is a shear stress (g/cm·sec²) of the piezoelectric resonator, N is an overtone order, F is a nominal frequency (Hz), and ΔF is a frequency variation (Hz) in the piezoelectric resonator before and after the reaction.

However, when the substance that adds the mass to the piezoelectric resonator exceed a certain size, there is known a phenomenon in which the substance that adds the mass starts to oscillate at a unique frequency different from that of the piezoelectric resonator, and the relation of the above-described formula (1), that is, the decrease of the oscillation frequency, does not work.

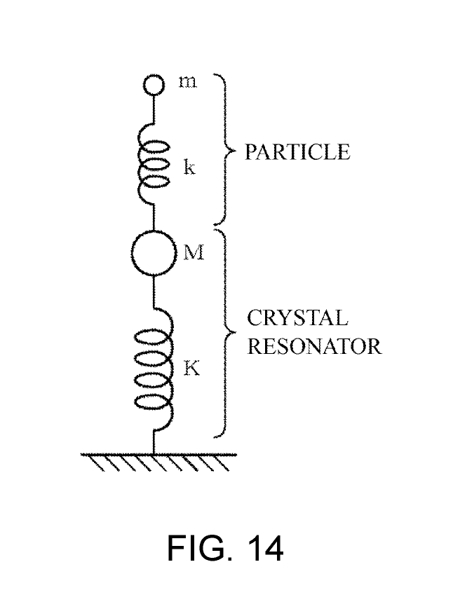

The following describes this phenomenon with reference to FIG. 14. A state where a sphere body 83 is simply bound to a crystal resonator 8 as illustrated in FIG. 14 is considered. It is assumed that a mass of the crystal resonator 8 is M, a mass of the sphere body 83 is in, and oscillations of the crystal resonator 8 and the sphere body 83 alone are oscillations of springs with respective spring constants K and k. Since the crystal resonator 8 and the sphere body 83 are bound, a resonance in a state of binding two springs in series as illustrated in FIG. 14 is generated.

In the case of the liquid phase, since a liquid is interposed between the sensitizer particle 82, the biotinylated antibody 80, the antigen 81, and the excitation electrode 42A, the oscillation is easily transmitted to the sensitizer particle 82, the biotinylated antibody 80, and the antigen 81 when the crystal resonator 4 is oscillated. Therefore, a combination resonance easily occurs. Accordingly, removing the liquid component in the supply channel and causing the oscillation in a state of contacting the gas phase as described above ensures restraining the combination resonance. As a result of this, a sensitization effect by adsorbing the sensitizer particles 82 can certainly be obtained and the sensing object can be sensed with high accuracy.

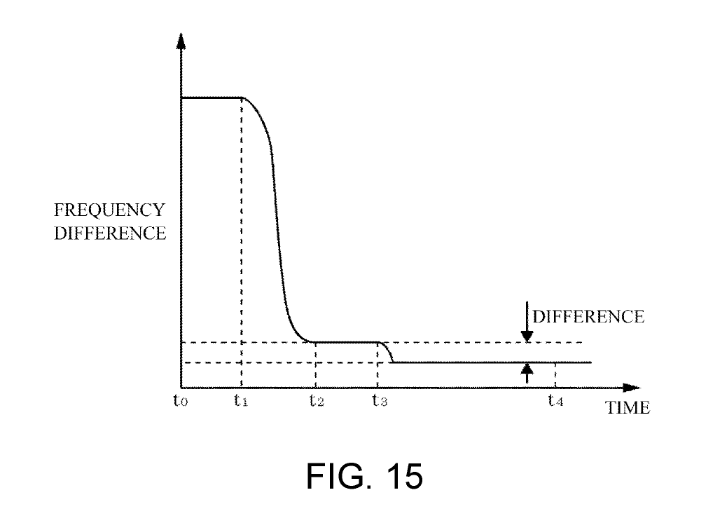

Furthermore, in the case where the crystal resonator 4 contacts the liquid phase when the crystal resonator 4 is oscillated, a crystal impedance (CI) grows large by an influence of, for example, viscosity of the liquid phase and the oscillation is less likely to be generated. For example, as illustrated in FIG. 15, first, at Time t1, after the buffer solution is supplied to the sensing sensor 2 and the excitation electrodes 42A and 42B are brought into contact with the liquid phase, a measurement of the oscillation frequency is performed. The following describes the case where the sample solution 50, the liquid 91 containing the sensitizer particles 82, and the liquid 92 containing the crosslinking agent are supplied thereafter, and a measurement of the oscillation frequency is performed to obtain a variation amount of the oscillation frequency.

The variation amount of the frequency of the first vibrating region 61 before and after supplying the sample solution 50, the liquid 91 containing the sensitizer particles 82, and the liquid 92 containing the crosslinking agent in this case becomes a frequency decreased from the oscillation frequency of the crystal resonator 4 under the liquid phase by the effect of mass addition caused by the attachment of the sensitizer particles 82, the biotinylated antibodies 80, and the antigens 81. However, since the oscillation becomes weak in a state where the excitation electrodes 42A and 42B contact the liquid phase, the variation amount of the frequency difference is small compared with the oscillation in a state where the excitation electrodes 42A and 42B contact the gas phase as illustrated in FIG. 7. Accordingly, the oscillation in a state where the excitation electrodes 42A and 42B contact the gas phase causes easy detection of the variation amount of the frequency by the effect of mass addition.

In the case where the measurement is performed with the surfaces of the excitation electrodes 42A and 42B being in the liquid phase, a noise caused by the excitation electrodes 42A and 42B being exposed to the liquid phase, such as an injection shock when the liquid is injected into the supply channel 57, can be removed. Accordingly, replacing the inside of the supply channel 57 by the gas phase to cause the excitation electrodes 42A and 42B not to contact the liquid phase restrains the decrease of the crystal impedance, thus restraining the measurement error of the oscillation frequency.

The attachment of the droplets on the excitation electrodes 42A and 42B possibly decreases the oscillation frequency by the effect of mass addition of the droplets. Replacing the pure water by the methanol 94, which easily evaporates, does not leave the droplets even after the liquid component is suctioned from the supply channel 57, thereby improving the measurement accuracy of the oscillation frequency.

The sample solution 50, the liquid 90 containing the biotinylated antibodies, and the liquid 91 containing the sensitizer particles may be mixed in advance to be supplied to the sensing sensor 2. Furthermore, this mixture may be supplied to the sensing sensor 2 after being mixed with the liquid 92 containing the crosslinking agent.

Alternatively, after supplying the liquid 91 containing the sensitizer particles to the sensing sensor 2, the liquid 92 containing the crosslinking agent is not necessarily be added. In this case, it is preferred to gently clean the surface of the sensing sensor 2 afterwards. In the process of supplying the pure water and the process of supplying the ethanol, gradually supplying the respective pure water and ethanol so as not to separate the sensitizer particles from the adsorbing layer can provide a similar effect. However, in the case where an operator performs the cleaning operation, a skill of the operator varies. In view of this, it is preferred to use the crosslinking agent. In the case where the cleaning operation is automatically performed, it is preferred to use the crosslinking agent from a standpoint of performing the process promptly.

Without adding the liquid 91 containing the sensitizer particles, only the liquid 92 containing the crosslinking agent may be added. Furthermore, the bind between the antibody and the sensitizer particle is not limited to a structure using the bind of the biotinylated antibody and the avidin, a structure in which the antibody is directly added to the sensitizer particle may be employed. The sensitizer particle is not limited to the gold colloid, but may be, for example, latex and magnetic beads.

### Working Example

The following test was performed to confirm the effect of the sensing method according to the embodiment of the present invention.

As the working example, a sample solution containing the antigens for 100 ng/ml was used. In the process described in the embodiment, the sample solution, a liquid containing the biotinylated antibodies, and a liquid containing the sensitizer particles were mixed in advance and the mixture was injected to the sensing sensor. Then, a process similar to the above-described embodiment was performed to measure the oscillation frequency.

As a comparative example, the oscillation frequencies were measured before supplying the solution containing the antigens in the working example, when the supply channel is filled with the buffer solution and after supplying the sensitizer particles, before supplying the crosslinking agent. Then, the variation amount of the frequencies was obtained.

While in the comparative example, the variation amount of the frequencies before and after supplying the sample solution was 29 Hz, the frequency variation amount in the working example was 1021 Hz. Accordingly, measuring the oscillation frequency after the surface of the electrode is caused to be in the gas phase after the sample solution is flown through provides approximately 35 times larger frequency variation amount and improves a detection sensitivity. Therefore, using the sensing method according to the embodiment of the present invention ensures obtaining a significant effect.

### DESCRIPTION OF REFERENCE SIGNS

2 sensing sensor
4 crystal resonator
10 sponge
12 oscillator circuit unit
42A, 42B excitation electrode
46 adsorbing layer
47 supply channel
63 first oscillator circuit
64 second oscillator circuit
80 biotinylated antibody
81 antigen
82 sensitizer particle

1. A sensing method that uses a sensing sensor made by forming an adsorbing layer on a surface of an electrode of a piezoelectric resonator, the adsorbing layer adsorbing a component as a sensing object in a sample solution, and supplying the sample solution to a measurement region of the sensing sensor to measure an amount of the component as an amount of frequency variation of the piezoelectric resonator before and after adsorption, the sensing method comprising:
oscillating the piezoelectric resonator using an oscillator circuit and measuring an oscillation frequency before the measurement region becomes in a liquid phase;
subsequently supplying the sample solution to the measurement region;
subsequently removing a liquid from the measurement region so as to cause the measurement region to be in a gas phase;
subsequently measuring an oscillation frequency by oscillating the piezoelectric resonator using the oscillator circuit, and measuring an amount of frequency variation between the oscillation frequency and the oscillation frequency before the measurement region becomes in the liquid phase.

2. The sensing method according to claim 1, further comprising:
supplying a liquid to the measurement region after supplying the sample solution to the measurement region and before causing the measurement region to be in the gas phase,
wherein the liquid containing a group of particles for sensitization having a property of adsorbing on a corresponding portion of the sensing object.

3. The sensing method according to claim 1, further comprising:
supplying a crosslinking agent that forms a cross-linkage between the sensing object and the adsorbing layer to the measurement region, after supplying the sample solution to the measurement region and before causing the measurement region to be in the gas phase.

4. The sensing method according to claim 2, further comprising:
supplying a crosslinking agent that forms cross-linkages between the particles having the property of adsorbing on the corresponding portion of the sensing object and the sensing object, and between the sensing object and the adsorbing layer to the measurement region, after supplying the liquid containing the group of particles for sensitization having the property of adsorbing on the corresponding portion of the sensing object and before causing the measurement region to be in the gas phase.

5. The sensing method according to claim 1, further comprising:
supplying a buffer solution to the measurement region, before the step of supplying the sample solution to the measurement region.

6. The sensing method according to claim 1, further comprising:
supplying an organic solvent to the measurement region before causing the measurement region to be in the gas phase, and
causing the measurement region to be in the gas phase includes removing the organic solvent to cause the measurement region to be in a gas phase.
